(19) United States
(12) Patent Application Publication
(10) Pub. No.: US 2011/0262680 A1
(43) Pub. Date: Oct. 27, 2011

(54) SILICON CARBIDE SUBSTRATE AND METHOD FOR MANUFACTURING SILICON CARBIDE SUBSTRATE

(75) Inventors: Taro Nishiguchi, Itami-shi (JP); Shin Harada, Osaka-shi (JP); Hiroki Inoue, Itami-shi (JP); Makoto Sasaki, Itami-shi (JP)

(73) Assignee: SUMITOMO ELECTRIC INDUSTRIES, LTD., Osaka-shi (JP)

(21) Appl. No.: 13/093,116

(22) Filed: Apr. 25, 2011

(30) Foreign Application Priority Data
Apr. 26, 2010 (JP) 2010-101153

(51) Int. Cl. C30B 23/02; B32B 3/14

(52) U.S. Cl. 428/78; 117/106

(57) ABSTRACT

A sublimation preventing layer is formed to cover a first region of a main surface of a material substrate. First and second single-crystal layers are arranged on the material substrate such that a gap between first and second side surfaces is located over the sublimation preventing layer. The material substrate and the first and second single-crystal layers are heated to sublimate silicon carbide from a second region of the main surface and recrystallize the sublimated silicon carbide on the first backside surface of the first single-crystal layer and the second backside surface of the second single-crystal layer, thereby forming a base substrate connected to each of the first and second backside surfaces. This can prevent formation of voids in a silicon carbide substrate having such a plurality of single-crystal layers.

### BACKGROUND OF THE INVENTION

1. Field of the Invention

The present invention relates to a silicon carbide substrate and a method for manufacturing the silicon carbide substrate, in particular, a silicon carbide substrate having a plurality of single-crystal layers and a method for manufacturing such a silicon carbide substrate.

2. Description of the Background Art

In recent years, SiC (silicon carbide) substrates have been adopted as semiconductor substrates for use in manufacturing semiconductor devices. SiC has a band gap larger than that of Si (silicon), which has been used more commonly. Hence, a semiconductor device employing a SiC substrate advantageously has a large reverse breakdown voltage, low on-resistance, and properties less likely to decrease in a high temperature environment.

In order to efficiently manufacture such semiconductor devices, the substrates need to be large in size to some extent. According to U.S. Pat. No. 7,314,520, a SiC substrate of 76 mm (3 inches) or greater can be manufactured.

Industrially, the size of a SiC single-crystal substrate is still limited to approximately 100 mm (4 inches). Accordingly, semiconductor devices cannot be efficiently manufactured using large single-crystal substrates, disadvantageously. This disadvantage becomes particularly serious in the case of using a property of a plane other than the (0001) plane in SiC of hexagonal system. Hereinafter, this will be described.

A SiC single-crystal substrate small in defect is usually manufactured by slicing a SiC ingot obtained by growth in the (0001) plane, which is less likely to cause stacking fault. Hence, a single-crystal substrate having a plane orientation other than the (0001) plane is obtained by slicing the ingot not in parallel with its grown surface. This makes it difficult to sufficiently secure the size of the single-crystal substrate, or many portions in the ingot cannot be used effectively. For this reason, it is particularly difficult to effectively manufacture a semiconductor device that employs a plane other than the (0001) plane of SiC.

Instead of increasing the size of such a SiC single-crystal substrate with difficulty, it is considered to use a silicon carbide substrate having a base substrate and a plurality of small single-crystal layers each connected to the base substrate. The size of this silicon carbide substrate can be increased by increasing the number of single-crystal layers as required. The base substrate connected to each of the plurality of single-crystal layers can be formed by recrystallizing sublimated silicon carbide on the plurality of single-crystal layers. However, in the case where the base substrate is thus formed by the sublimation and the recrystallization, a multiplicity of voids are formed in the base substrate at locations between the plurality of single-crystal layers when viewed in a planar view. This results in decreased mechanical strength of the base substrate. In an extreme case, the voids may be connected in the direction of thickness to form a through hole in the silicon carbide substrate. Existence of such a through hole causes a liquid such as a photoresist to leak therethrough in a process of manufacturing a semiconductor device using the silicon carbide substrate.

### SUMMARY OF THE INVENTION

The present invention has been made in view of the above-described problem, and its object is to provide a silicon carbide substrate and a method for manufacturing a silicon carbide substrate, so as to prevent formation of voids in a silicon carbide substrate having a plurality of single-crystal layers.

A method for manufacturing a silicon carbide substrate in the present invention includes the following steps.

There is prepared a material substrate, which has a main surface having first and second regions and is made of silicon carbide. A sublimation preventing layer is formed which is made of a material having a solid state at a sublimation temperature of silicon carbide and covers only the first region of the first and second regions of the main surface. On the material substrate, first and second single-crystal layers each made of silicon carbide are arranged. The first single-crystal layer has a first backside surface, a first front-side surface opposite to the first backside surface, and a first side surface connecting the first backside surface and the first front-side surface to each other. The second single-crystal layer has a second backside surface, a second front-side surface opposite to the second backside surface, and a second side surface connecting the second backside surface and the second front-side surface to each other. The step of arranging the first and second single-crystal layers is performed such that each of the first and second backside surfaces has a portion facing the second region and that a gap between the first and second side surfaces is located over the sublimation preventing layer. A base substrate is formed which is connected to each of the first and second backside surfaces by heating the material substrate and the first and second single-crystal layers such that a temperature of the main surface reaches the sublimation temperature of silicon carbide and a temperature of each of the first and second backside surfaces becomes lower than the temperature of the main surface, so as to sublimate silicon carbide from the second region and recrystallize the sublimated silicon carbide on each of the first and second backside surfaces.

According to this method for manufacturing, the gap between the first and second side surfaces is located over the sublimation preventing layer formed on the material substrate. This prevents silicon carbide from being sublimated from the material substrate into the gap upon forming the base substrate by heating the material substrate. Thus, voids, which are generated due to the sublimation of silicon carbide into the gap, are prevented from being formed.

Preferably in the method for manufacturing, the step of arranging the first and second single-crystal layers is performed to allow each of the first and second backside surfaces to have a portion in contact with the sublimation preventing layer formed on the main surface. Accordingly, a space is retained between the second region, which is in the main surface and does not have the sublimation preventing layer formed thereon, and each of the first and second backside surfaces. This space allows the temperature of each of the first and second backside surfaces to be lower than that of the main surface. Accordingly, the recrystallization of silicon carbide on the first and second backside surfaces can be facilitated, thereby efficiently manufacturing the silicon carbide substrate.

Preferably in the method for manufacturing, the above-described material is carbon. This allows the material of the sublimation preventing layer to have a solid state at the sublimation temperature of silicon carbide.

In the method for manufacturing, the step of forming the sublimation preventing layer may be performed using a sputtering method. Alternatively, the step of forming the sublimation preventing layer may include the steps of: applying a fluid containing carbon atoms onto the first region; and carbonizing the fluid thus applied. The fluid may be an adhesive agent or a photoresist.

A silicon carbide substrate of the present invention includes a base substrate, a sublimation preventing layer, and first and second single-crystal layers. The base substrate has a main surface and is made of silicon carbide. The sublimation preventing layer is made of a material having a solid state at a sublimation temperature of silicon carbide, and covers a portion of the main surface. The first and second single-crystal layers are arranged on the base substrate and made of silicon carbide. The first single-crystal layer has a first backside surface, a first front-side surface opposite to the first backside surface, and a first side surface connecting the first backside surface and the first front-side surface to each other. The second single-crystal layer has a second backside surface, a second front-side surface opposite to the second backside surface, and a second side surface connecting the second backside surface and the second front-side surface to each other. Each of the first and second backside surfaces is connected to the base substrate. A gap between the first and second side surfaces is located over the sublimation preventing layer.

According to the silicon carbide substrate, the gap between the first and second side surfaces is located over the sublimation preventing layer formed on the base substrate. This prevents silicon carbide from being sublimated from the material substrate into the gap upon heating the material substrate for forming the base substrate. Accordingly, voids, which are generated due to the sublimation of silicon carbide into the gap, can be prevented from being formed.

As apparent from the description above, according to the present invention, voids can be prevented from being formed in a silicon carbide substrate having a plurality of single-crystal layers.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a configuration of a silicon carbide substrate in a first embodiment of the present invention.

FIG. 2 is a schematic cross sectional view taken along a line II-II in FIG. 1.

FIG. 3A is a plan view schematically showing a first step of a method for manufacturing the silicon carbide substrate in the first embodiment of the present invention.

FIG. 3B is a schematic cross sectional view taken along a line IIIB-IIIB in FIG. 3A.

FIG. 4A is a plan view schematically showing a second step of the method for manufacturing the silicon carbide substrate in the first embodiment of the present invention.

FIG. 4B is a schematic cross sectional view taken along a line IVB-IVB in FIG. 4A.

FIG. 5A is a plan view schematically showing a third step of the method for manufacturing the silicon carbide substrate in the first embodiment of the present invention.

FIG. 5B is a schematic cross sectional view taken along a line VB-VB in FIG. 5A.

FIG. 6 and FIG. 7 are partial cross sectional views schematically showing first and second steps of a method for manufacturing a silicon carbide substrate in a comparative example.

FIG. 8 and FIG. 9 are cross sectional views schematically showing first and second steps of a method for manufacturing a silicon carbide substrate in a second embodiment of the present invention.

FIG. 10 is a plan view schematically showing a configuration of a silicon carbide substrate in a third embodiment of the present invention.

FIG. 11 is a partial cross sectional view schematically showing a configuration of a semiconductor device in a fourth embodiment of the present invention.

FIG. 12 is a schematic flowchart showing a method for manufacturing the semiconductor device in the fourth embodiment of the present invention.

FIG. 13-FIG. 17 are partial cross sectional views schematically showing first to fifth steps of the method for manufacturing the semiconductor device in the fourth embodiment of the present invention.

### DESCRIPTION OF THE PREFERRED EMBODIMENTS

The following describes embodiments of the present invention with reference to figures.

### First Embodiment

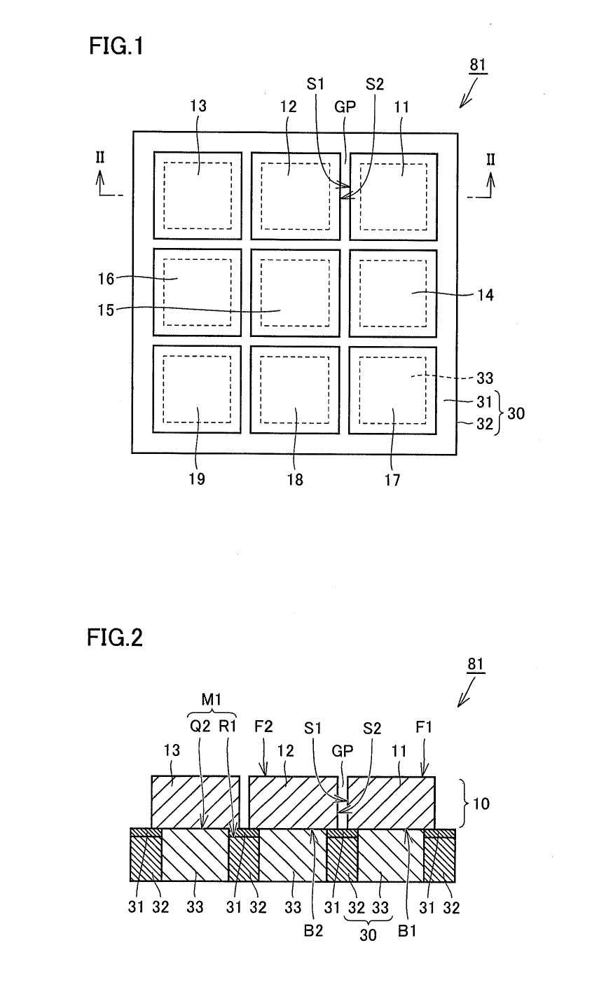

Referring to FIG. 1 and FIG. 2, a silicon carbide substrate 81 includes a base substrate 30, a sublimation preventing layer 31, and single-crystal layers 11-19 (also collectively referred to as “single-crystal layer 10”).

Base substrate 30 is made of silicon carbide, and has a non-growth portion 32 and regrowth portions 33. An interface between non-growth portion 32 and each regrowth portion 33 extends substantially in the direction of thickness (vertical direction in FIG. 2). Only regrowth portions 33 of non-growth portion 32 and regrowth portions 33 are portions formed by recrystallizing silicon carbide on single-crystal layer 10. Hence, only regrowth portions 33 of non-growth portion 32 and regrowth portions 33 are epitaxially grown under influence of the crystal structure of single-crystal layer 10. Accordingly, there is a crystallographic difference between non-growth portion 32 and each regrowth portion 33. Further, base substrate 30 has a main surface M1 (upper surface in FIG. 2) having a region R1 (first region) and regions Q2 (second region). Region R1 is formed of non-growth portion 32, whereas regions Q2 are formed of regrowth portions 33.

Single-crystal layers 11-19 (single-crystal layer 10) are arranged on base substrate 30 in the form of matrix. Each of single-crystal layers 11-19 is made of silicon carbide having a single-crystal structure. Single-crystal layer 11 (first single-crystal layer) has a backside surface B1 (first backside surface), a front-side surface F1 (first front-side surface) opposite to backside surface B1, and a side surface S1 (first side surface) connecting backside surface B1 and front-side surface F1 to each other. Similarly, single-crystal layer 12 (second single-crystal layer) has a backside surface B2 (second backside surface), a front-side surface F2 (second front-side surface) opposite to second backside surface B2, and a side surface S2 (second side surface) connecting backside surface B2 and front-side surface F2 to each other. Each of backside surface B1 of single-crystal layer 11 and backside surface B2 of single-crystal layer 12 is connected to base substrate 30. The other single-crystal layers 13-19 have configurations similar thereto.

Sublimation preventing layer 31 is made of a material having a solid state at the sublimation temperature of silicon carbide. An example of such a material is carbon. Sublimation preventing layer 31 only covers a part of main surface M1 of base substrate 30, i.e., region R1, and does not cover regions Q2. A gap GP is formed in a region interposed between single-crystal layers 11 and 12, i.e., a region interposed between side surfaces S1 and S2. Gap GP is located over sublimation preventing layer 31. Further, each of backside surfaces B1 and B2 has an edge located on sublimation preventing layer 31.

The following describes a method for manufacturing silicon carbide substrate 81. For ease of description, only single-crystal layers 11 and 12 of single-crystal layers 11-19 may be explained, but each of single-crystal layers 11-19 is handled in the same manner.

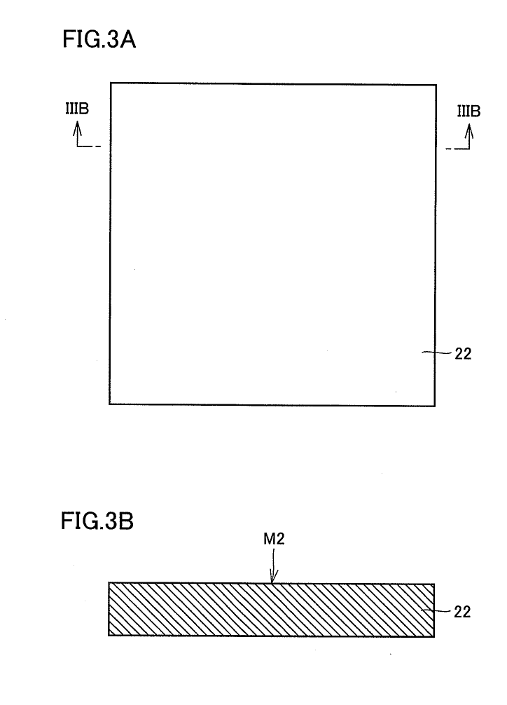

Referring to FIG. 3A and FIG. 3B, first, a material substrate 22 is prepared which has a main surface M2 and is made of silicon carbide. Preferably, main surface M2 is planarized. Material substrate 22 may have any of single-crystal, polycrystal, and amorphous structures, but preferably has a crystal structure similar to those of single-crystal layers 11-19. The planar shape of material substrate 22 is not particularly limited, and is a quadrangular shape in the present embodiment. Instead of the quadrangular shape, a circular shape may be used. In this case, the diameter of the circular shape is preferably 5 cm or greater, more preferably, 15 cm or greater.

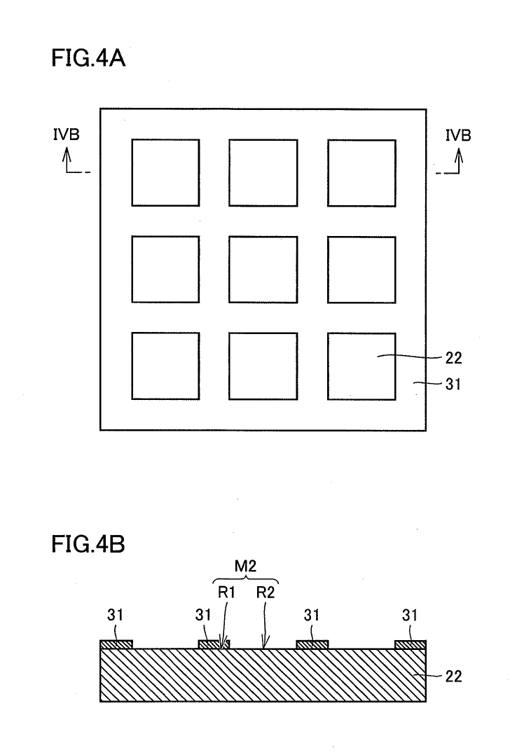

Referring to FIG. 4A and FIG. 4B, main surface M2 of material substrate 22 has region R1 (first region) and regions R2 (second region). Sublimation preventing layer 31 is formed to only cover region R1 of regions R1 and R2, selectively. Namely, sublimation preventing layer 31 is selectively formed on region R1. As a method of depositing sublimation preventing layer 31, a general film forming method can be used such as a sputtering method. In order to thus selectively form sublimation preventing layer 31 only on region R1 of main surface M2, there may be used a metal mask which exposes region R1 and covers regions R2, for example.

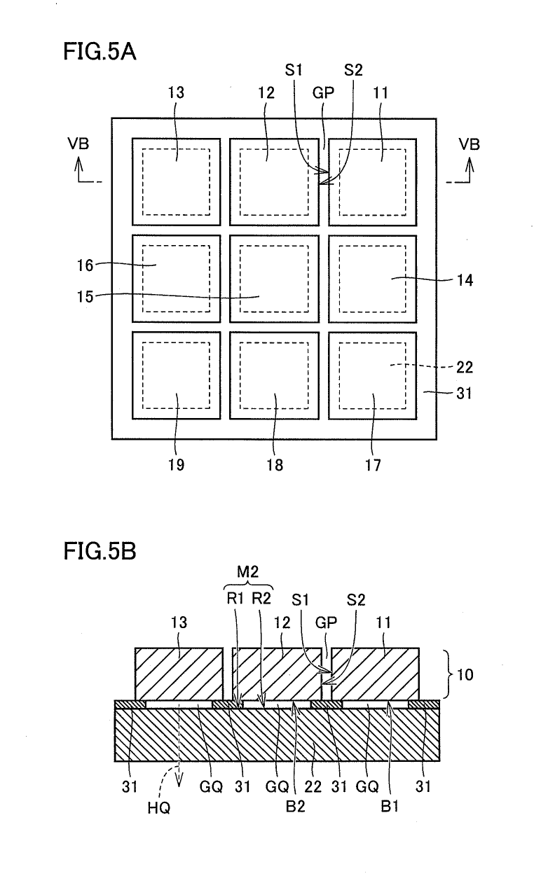

Referring to FIG. 5A and FIG. 5B, single-crystal layers 11-19 are arranged on material substrate 22 in the form of matrix. Single-crystal layers 11 and 12 are arranged such that each of backside surfaces B1 and B2 has a portion facing region R2 and gap GP between side surfaces S1 and S2 are located over sublimation preventing layer 31. Further, in the present embodiment, in the previous step (FIG. 4A and FIG. 4B), sublimation preventing layer 31 is formed to project from main surface M2 by its thickness, and in this step (FIG. 5A and FIG. 5B), a portion of backside surfaces B1, B2 is brought into contact with sublimation preventing layer 31 thus projecting from main surface M2. More specifically, the edge of each of backside surfaces B1 and B2 is brought into contact with sublimation preventing layer 31. Accordingly, a space GQ is retained between region R2 of material substrate 22 and each of backside surface B1 of single-crystal layer 11 and backside surface B2 of single-crystal layer 12.

Next, material substrate 22 and single-crystal layers 11 and 12 are heated such that the temperature of main surface M2 of material substrate 22 reaches the sublimation temperature of silicon carbide and the temperature of each of backside surfaces B1 and B2 becomes lower than that of main surface M2, so as to sublimate silicon carbide from regions R2. The silicon carbide thus sublimated is recrystallized on each of backside surfaces B1 and B2, thereby forming base substrate 30 (FIG. 2) in which backside surfaces B1 and B2 are connected to each other. The following describes this heating step in detail.

First, in a container of a heating device, single-crystal layers 11-19 are arranged on material substrate 22 as described above. This container preferably has a high heat resistance, and is made of, for example, graphite. Next, atmosphere in the heating device may be adopted to be an inert gas. An exemplary inert gas usable is a noble gas such as He or Ar; a nitrogen gas; or a mixed gas of the noble gas and nitrogen gas. Alternatively, this atmosphere may be one obtained by simply reducing pressure of the atmospheric air. Further, the pressure in the heating device is preferably 50 kPa or smaller, and is more preferably 10 kPa or smaller.

Then, the heating device heats single-crystal layers 11-19 (single-crystal layer 10) and material substrate 22. They are heated to bring at least the temperature of material substrate 22 to a temperature equal to or higher than the sublimation temperature of silicon carbide. Specifically, a setting temperature for the heating device is more than 1800° C. and less than 2300° C. For example, the setting temperature is 2000° C. When the temperature is 1800° C. or smaller, the heating is likely to be insufficient for sublimation of silicon carbide. On the other hand, when the temperature is 2300° C. or greater, the surface of single-crystal layer 10 is likely to be notably rough. Further, this heating is performed to form a temperature gradient such that the temperature is decreased from the lower side to the upper side in FIG. 5B. The temperature gradient is preferably not less than 1° C./cm and not more than 200° C./cm, more preferably, not less than 10° C./cm and not more than 50° C./cm. With the temperature gradient thus provided in the direction of thickness (vertical direction in FIG. 5B), the temperature of each of backside surfaces B1 and B2 becomes smaller than that of main surface M2 by a temperature difference corresponding to a product of the temperature gradient and the thickness of space GQ. As a result, sublimation reaction of silicon carbide is more likely to take place from material substrate 22 into space GQ, as compared with that from single-crystal substrates 11 and 12 thereinto. On the other hand, recrystallization reaction resulting from the supply of the silicon carbide material from space GQ is more likely to take place on single-crystal layers 11 and 12 as compared with on material substrate 22. As a result, as indicated by a broken line arrow HQ (FIG. 5B), space GQ is transferred due to the sublimation/recrystallization reaction. More specifically, space GQ is first divided into a multiplicity of voids in material substrate 22. Then, these voids are transferred in a direction indicated by arrow HQ to eliminate them from material substrate 22.

The portions corresponding to regions R2 in material substrate 22 when viewed in a planar view are changed by the above-described sublimation/recrystallization reaction into regrowth portions 33 (FIG. 2) epitaxially formed on the backside surface of single-crystal layer 10. Accordingly, regrowth portions 33 connected to single-crystal layer 10 are formed. Meanwhile, the portion corresponding to region R1 in material substrate 22 when viewed in a planar view is covered with sublimation preventing layer 31. Hence, sublimation does not take place therefrom, and the portion remains as non-growth portion 32 (FIG. 2). In this way, silicon carbide substrate 81 (FIG. 2) is obtained which includes base substrate 30 having non-growth portion 32 and regrowth portions 33.

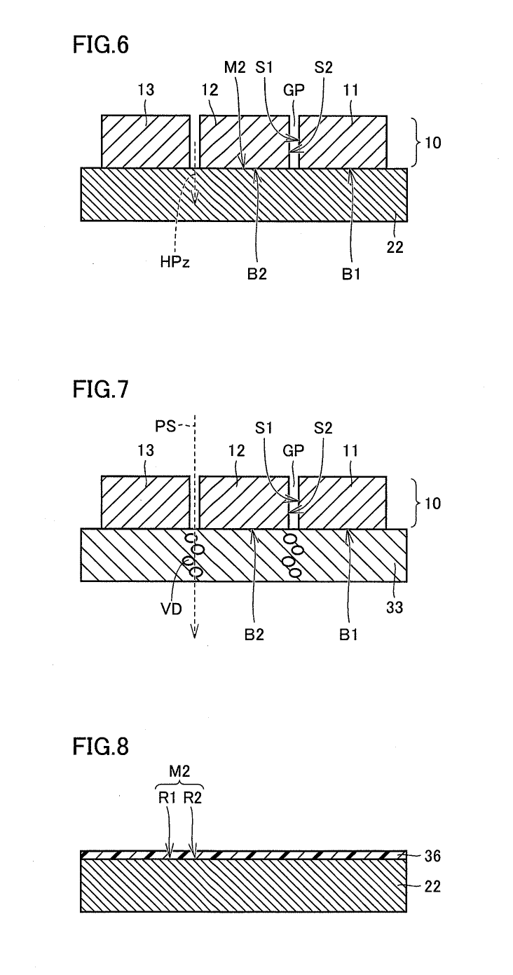

Referring to FIG. 6 and FIG. 7, the following describes a method for manufacturing a silicon carbide substrate in a comparative example.

In this comparative example, sublimation preventing layer 31 (FIG. 5B) is not formed on material substrate 22. Accordingly, in the heating step, sublimation of silicon carbide takes place to gap GP from the portion of material substrate 22 that faces gap GP. As a result, a multiplicity of voids VD are generated in material substrate 22 in a direction indicated by a broken line arrow HPz. Voids VD result in decreased mechanical strength of the silicon carbide substrate. In an extreme case, voids VD may be connected in the direction of thickness to form a through hole in the silicon carbide substrate. Existence of such a through hole causes a liquid such as a photoresist to leak therethrough as indicated by a broken line arrow PS in a process of manufacturing a semiconductor device using the silicon carbide substrate.

Further, in this comparative example, space GQ (FIG. 5B) is not formed unlike in the present embodiment. Accordingly, it becomes difficult to attain a large temperature difference between main surface M2 and each of backside surfaces B1 and B2. This results in decreased rate of transfer of silicon carbide from main surface M2 to each of backside surfaces B1 and B2 in the sublimation/recrystallization reaction, thereby decreasing the rate of forming regrowth portions 33 and accordingly resulting in decreased manufacturing efficiency of the silicon carbide substrate.

In contrast, according to the present embodiment, gap GP between side surfaces S1 and S2 is formed over sublimation preventing layer 31 formed on material substrate 22 (FIG. 5B). Accordingly, silicon carbide is prevented from being sublimated from material substrate 22 into gap GP even when material substrate 22 is heated up to the sublimation temperature of silicon carbide. This can prevent generation of voids caused by sublimation of silicon carbide to gap GP upon forming base substrate 30 (FIG. 2) using material substrate 22.

Further, sublimation preventing layer 31 serves as a spacer to form space GQ (FIG. 5B), thus allowing for a large temperature difference between main surface M2 and each of backside surfaces B1 and B2. This increases a rate of transfer of silicon carbide from main surface M2 to each of backside surfaces B1 and B2 in the sublimation/recrystallization reaction, thereby increasing the rate of forming regrowth portions 33 to improve manufacturing efficiency of the silicon carbide substrate.

Sublimation preventing layer 31 preferably has a thickness of 1 mm or smaller, more preferably, 100 μm or smaller, further preferably, approximately several ten p.m. For example, sublimation preventing layer 31 has a thickness of 20-30 μm. If the thickness of sublimation preventing layer 31 is too small, the thickness of space GQ (FIG. 5B) also becomes small, which decreases the above-described effect of improving the manufacturing efficiency provided by space GQ. On the other hand, if the thickness of sublimation preventing layer 31 is too large, silicon carbide is likely to get out of space GQ, which results in decreased rate of recrystallizing silicon carbide on backside surfaces B1 and B2. Accordingly, the efficiency in manufacturing silicon carbide substrate 81 is decreased.

It should be noted that instead of carbon, sublimation preventing layer 31 may be made of the other material having a solid state at the sublimation temperature of silicon carbide. Specifically, a refractory metal can be used therefor. An example of such a refractory metal usable is tantalum, tungsten, molybdenum, titanium, zirconium, or hafnium.

Silicon carbide substrate 81 preferably has a certain thickness (size in the vertical direction in FIG. 2) to facilitate handling thereof in the process of manufacturing semiconductor devices using silicon carbide substrate 81. For example, silicon carbide substrate 81 preferably has a thickness of 300 μm or greater. Further, silicon carbide substrate 81 has, for example, a square planar shape with sides of 60 mm.

Preferably, each of single-crystal layers 11-19 has a hexagonal crystal structure, more preferably, has an off angle of not less than 50° and not more than 65° relative to the {0001} plane, and further preferably has a plane orientation of {03-38}. However, {0001}, {11-20}, or {1-100} can be also employed as a preferable plane orientation. Further, there can be employed a plane that is off by several degrees relative to each of the above-described plane orientations. Of various polytypes of the hexagonal crystal, polytype 4H is particularly preferable. For example, each of single-crystal layers 11-19 has a planar shape of 20×20 mm, a thickness of 300 μm, 4H polytype, a plane orientation of {03-38}, an n type impurity concentration of 1×10¹⁹ cm⁻³, a resistivity of 5 mΩ·cm, a micro pipe density of 0.2 cm⁻², and a stacking fault density of less than 1 cm⁻¹.

Non-growth portion 32 (FIG. 2) may have any of single-crystal, polycrystal, and amorphous structures, but preferably has a crystal structure similar to those of single-crystal layers 11-19. However, an amount of defect in base substrate 30 including non-growth portion 32 may be greater than those in single-crystal layers 11-19. As such, since the requirement of the amount of defect is not so strict for base substrate 30, the impurity concentration in base substrate 30 can be readily increased as compared with those in single-crystal layers 11-19. This impurity concentration is preferably set at 5×10¹⁸ cm⁻³ or greater, more preferably, 1×10²⁰ cm⁻³ or greater. With the impurity concentration thus high, base substrate 30 can have a small electrical resistivity. This electrical resistivity is preferably less than 50 mΩ·cm, more preferably, less than 10 mΩ·cm. By using such a silicon carbide substrate 81 to manufacture a vertical type semiconductor device in which an electric current flows in the vertical direction such as a vertical type MOSFET (Metal Oxide Semiconductor Field Effect Transistor), on-resistance can be reduced in the vertical type semiconductor device.

Because the requirement for the amount of defect is not so strict for base substrate 30 as described above, base substrate 30 larger than each of single-crystal layers 11-19 can be readily fabricated. Base substrate 30 has a planar shape of 60×60 mm, a thickness of 300 μm, a polytype of 4H, a plane orientation of {03-38}, an n type impurity concentration of 1×10²⁰ cm⁻³, a micro pipe density of 1×10⁴ cm⁻², and a stacking fault density of 1×10⁵ cm⁻¹, for example.

Preferably, in order to prevent cracks of silicon carbide substrate 81, a difference is adapted to be as small as possible between the thermal expansion coefficient of base substrate 30 and the thermal expansion coefficient of each of single-crystal layers 11-19 in silicon carbide substrate 81. Accordingly, cracks and warpage of silicon carbide substrate 81 can be suppressed. Meanwhile, variation in the thickness of each of single-crystal layer 10 and material substrate 22 is preferably small, for example, is less than 10 μm.

### Second Embodiment

In the present embodiment, sublimation preventing layer 31 is formed on material substrate 22, using a method different from that of the first embodiment. Hereinafter, this method will be described.

Referring to FIG. 8, a photoresist (fluid) 36 is applied onto main surface M2 of material substrate 22. In other words, photoresist 36 is applied onto both regions R1 and R2. Next, photoresist 36 is exposed to light and developed using a photomask corresponding to a pattern of regions R1 and R2.

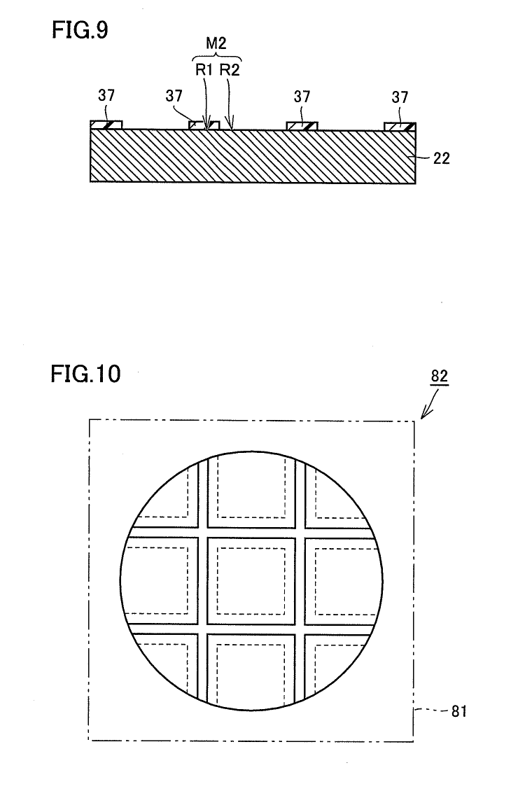

Referring to FIG. 9, the exposure and development allows for formation of a resist layer 37 only on region R1 of regions R1 and R2. Next, resist layer 37 is sintered and is accordingly carbonized. In this way, from resist layer 37, sublimation preventing layer 31 (FIG. 4A and FIG. 4B) is formed.

Apart from the configuration described above, the configuration of the second embodiment is substantially the same as the configuration of the first embodiment. Hence, the same or corresponding elements are given the same reference characters and are not described repeatedly.

The following describes a variation of the present embodiment. In the present variation, an adhesive agent is employed as the fluid instead of photoresist 36 (FIG. 8). This adhesive agent has flowability, and contains carbon as its main component. Further, this adhesive agent is applied selectively only onto region R1 of regions R1 and R2. Accordingly, an adhesive agent layer is formed instead of resist layer 37 (FIG. 9). Then, this adhesive agent layer is sintered and is accordingly carbonized. In this way, from the adhesive agent layer, sublimation preventing layer 31 (FIG. 4A and FIG. 4B) is formed.

### Third Embodiment

Referring to FIG. 10, a silicon carbide substrate 82 of the present embodiment is different from silicon carbide substrate 81 of the first embodiment (FIG. 1) in that silicon carbide substrate 82 has a circular shape. Silicon carbide substrate 82 is obtained by cutting silicon carbide substrate 81 (FIG. 1) to have a circular shape. Preferably, the diameter of the circular shape is 5 cm or greater, more preferably, 15 cm or greater. Apart from the configuration described above, the configuration of the third embodiment is substantially the same as the configuration of the first embodiment. Hence, the same or corresponding elements are given the same reference characters and are not described repeatedly.

### Fourth Embodiment

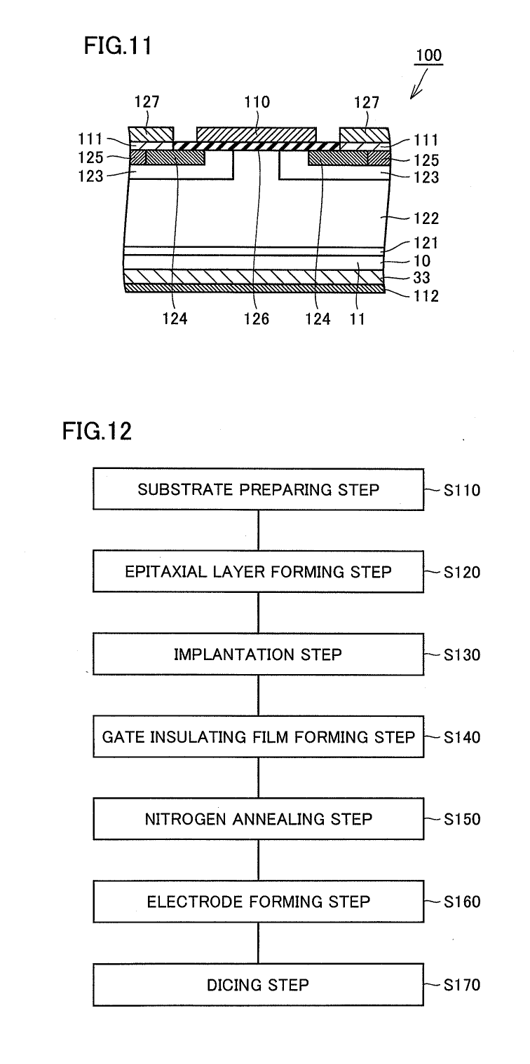

Referring to FIG. 11, a semiconductor device 100 of the present embodiment is a DiMOSFET (Double Implanted Metal Oxide Semiconductor Field Effect Transistor) of vertical type, and has a regrowth portion 33, single-crystal layer 10, a buffer layer 121, a reverse breakdown voltage holding layer 122, p regions 123, n⁺ regions 124, p⁺ regions 125, an oxide film 126, source electrodes 111, upper source electrodes 127, a gate electrode 110, and a drain electrode 112. Semiconductor device 100 has a planar shape (shape when viewed from upward in FIG. 11) of, for example, a rectangle or a square with sides each having a length of 2 mm or greater.

Drain electrode 112 is provided on regrowth portion 33 and buffer layer 121 is provided on single-crystal layer 10. With this arrangement, a region in which flow of carriers is controlled by gate electrode 110 is disposed not at the regrowth portion 33 side but at the single-crystal layer 10 side. Each of regrowth portion 33 and single-crystal layer 10 has n type conductivity in the present embodiment.

Buffer layer 121 has n type conductivity, and has a thickness of, for example, 0.5 μm. Further, impurity with n type conductivity in buffer layer 121 has a concentration of, for example, 5×10¹⁷ cm⁻³.

Reverse breakdown voltage holding layer 122 is formed on buffer layer 121, and is made of SiC with n type conductivity. For example, reverse breakdown voltage holding layer 122 has a thickness of 10 μm, and includes a conductive impurity of n type at a concentration of 5×10¹⁵ cm⁻³.

Reverse breakdown voltage holding layer 122 has a surface in which the plurality of p regions 123 of p type conductivity are formed with spaces therebetween. In each of p regions 123, an n⁺ region 124 is formed at the surface layer of p region 123. Further, at a location adjacent to n⁺ region 124, a p⁺ region 125 is formed. Oxide film 126 is formed on an exposed portion of reverse breakdown voltage holding layer 122 between the plurality of p regions 123. Specifically, oxide film 126 is formed to extend on n region 124 in one p region 123, p region 123, an exposed portion of reverse breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed.

The maximum value of the nitrogen atom concentration is 1×10²¹ cm⁻³ or greater in a region distant away by 10 nm or shorter from an interface between oxide film 126 and each of the semiconductor layers, i.e., n⁺ regions 124, p⁺ regions 125, p regions 123, and reverse breakdown voltage holding layer 122. This achieves improved mobility particularly in a channel region below oxide film 126 (a contact portion of each p region 123 with oxide film 126 between each of n⁺ regions 124 and reverse breakdown voltage holding layer 122).

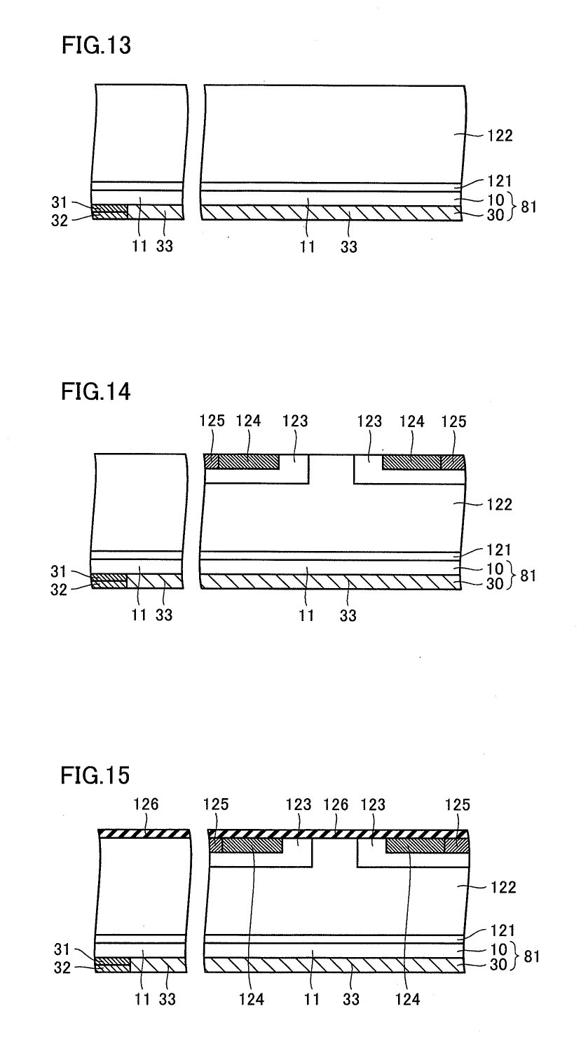

The following describes a method for manufacturing a semiconductor device 100. It should be noted that FIG. 13-FIG. 17 show steps only in the vicinity of single-crystal layer 11 of single-crystal layers 11-19 (FIG. 1), but the same steps are performed also in the vicinity of each of single-crystal layers 12-19.

First, in a substrate preparing step (step S110: FIG. 12), silicon carbide substrate 81 (FIG. 1 and FIG. 2) is prepared. Silicon carbide substrate 81 has n type conductivity.

Referring to FIG. 13, in an epitaxial layer forming step (step S120: FIG. 12), buffer layer 121 and reverse breakdown voltage holding layer 122 are formed as follows.

First, buffer layer 121 is formed on the front-side surface of silicon carbide substrate 81. Buffer layer 121 is made of SiC of n type conductivity, and is an epitaxial layer having a thickness of 0.5 μm, for example. Buffer layer 121 has a conductive impurity at a concentration of, for example, 5×10¹⁷ cm⁻³.

Next, reverse breakdown voltage holding layer 122 is formed on buffer layer 121. Specifically, a layer made of SiC of n type conductivity is formed using an epitaxial growth method. Reverse breakdown voltage holding layer 122 has a thickness of, for example, 10 μm. Further, reverse breakdown voltage holding layer 122 includes an impurity of n type conductivity at a concentration of, for example, 5×10¹⁵ cm⁻³.

Referring to FIG. 14, an implantation step (step S130: FIG. 12) is performed to form p regions 123, n⁺ regions 124, and p⁺ regions 125 as follows.

First, an impurity of p type conductivity is selectively implanted into portions of reverse breakdown voltage holding layer 122, thereby forming p regions 123. Then, a conductive impurity of n type is selectively implanted to predetermined regions to form n⁺ regions 124, and a conductive impurity of p type is selectively implanted into predetermined regions to form p⁺ regions 125. It should be noted that such selective implantation of the impurities is performed using a mask formed of for example, an oxide film.

After such an implantation step, an activation annealing process is performed. For example, the annealing is performed in argon atmosphere at a heating temperature of 1700° C. for 30 minutes.

Referring to FIG. 15, a gate insulating film forming step (step S140: FIG. 12) is performed. Specifically, oxide film 126 is formed to cover reverse breakdown voltage holding layer 122, p regions 123, n⁺ regions 124, and p⁺ regions 125. Oxide film 126 may be formed through dry oxidation (thermal oxidation). Conditions for the dry oxidation are, for example, as follows: the heating temperature is 1200° C. and the heating time is 30 minutes.

Thereafter, a nitrogen annealing step (step S150) is performed. Specifically, annealing process is performed in nitrogen monoxide (NO) atmosphere. Conditions for this process are, for example, as follows: the heating temperature is 1100° C. and the heating time is 120 minutes. As a result, nitrogen atoms are introduced into a vicinity of the interface between oxide film 126 and each of reverse breakdown voltage holding layer 122, p regions 123, n⁺ regions 124, and p⁺ regions 125.

It should be noted that after the annealing step using nitrogen monoxide, additional annealing process may be performed using argon (Ar) gas, which is an inert gas. Conditions for this process are, for example, as follows: the heating temperature is 1100° C. and the heating time is 60 minutes.

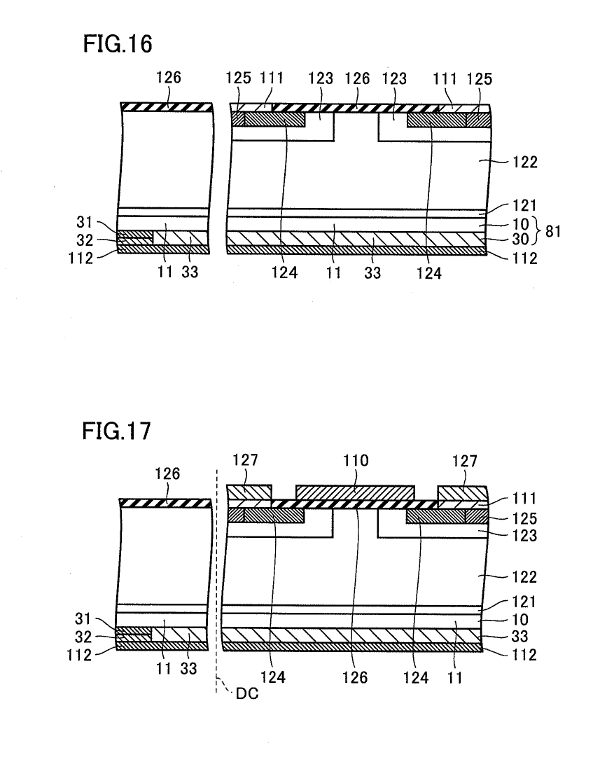

Referring to FIG. 16, an electrode forming step (step S160: FIG. 12) is performed to form source electrodes 111 and drain electrode 112 in the following manner.

First, a resist film having a pattern is formed on oxide film 126, using a photolithography method. Using the resist film as a mask, portions above n⁺ regions 124 and p⁺ regions 125 in oxide film 126 are removed by etching. In this way, openings are formed in oxide film 126. Next, in each of the openings, a conductive film is formed in contact with each of n⁺ regions 124 and p⁺ regions 125. Then, the resist film is removed, thus removing the conductive film's portions located on the resist film (lift-off). This conductive film may be a metal film, for example, may be made of nickel (Ni). As a result of the lift-off, source electrodes 111 are formed.

It should be noted that on this occasion, heat treatment for alloying is preferably performed. For example, the heat treatment is performed in atmosphere of argon (Ar) gas, which is an inert gas, at a heating temperature of 950° C. for two minutes.

Referring to FIG. 17 again, upper source electrodes 127 are formed on source electrodes 111. Further, gate electrode 110 is formed on oxide film 126. Further, drain electrode 112 is formed on the backside surface of silicon carbide substrate 81.

Next, in a dicing step (step S170: FIG. 12), dicing is performed as indicated by a broken line DC. Accordingly, a plurality of semiconductor devices 100 are obtained by the cutting. It should be noted that by this dicing, sublimation preventing layer 31 and non-growth portion 32 are removed.

It should be noted that a configuration may be employed in which conductive types are opposite to those in the present embodiment. Namely, a configuration may be employed in which p type and n type are replaced with each other. Further, the DiMOSFET of vertical type has been exemplified, but another semiconductor device may be manufactured using the semiconductor substrate of the present invention. For example, a RESURF-JFET (Reduced Surface Field-Junction Field Effect Transistor) or a Schottky diode may be manufactured.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide substrate, comprising the steps of:
preparing a material substrate, which has a main surface having first and second regions and is made of silicon carbide;
forming a sublimation preventing layer, which is made of a material having a solid state at a sublimation temperature of silicon carbide and covers only said first region of said first and second regions of said main surface;
arranging, on said material substrate, first and second single-crystal layers each made of silicon carbide, said first single-crystal layer having a first backside surface, a first front-side surface opposite to said first backside surface, and a first side surface connecting said first backside surface and said first front-side surface to each other, said second single-crystal layer having a second backside surface, a second front-side surface opposite to said second backside surface, and a second side surface connecting said second backside surface and said second front-side surface to each other, the step of arranging said first and second single-crystal layers being performed such that each of said first and second backside surfaces has a portion facing said second region and that a gap between said first and second side surfaces is located over said sublimation preventing layer; and
forming a base substrate connected to each of said first and second backside surfaces by heating said material substrate and said first and second single-crystal layers such that a temperature of said main surface reaches the sublimation temperature of silicon carbide and a temperature of each of said first and second backside surfaces becomes lower than the temperature of said main surface, so as to sublimate silicon carbide from said second region and recrystallize the sublimated silicon carbide on each of said first and second backside surfaces.

2. The method for manufacturing the silicon carbide substrate according to claim 1, wherein the step of arranging said first and second single-crystal layers is performed to allow each of said first and second backside surfaces to have a portion in contact with said sublimation preventing layer formed on said main surface.

3. The method for manufacturing the silicon carbide substrate according to claim 1, wherein the material of said sublimation preventing layer is carbon.

4. The method for manufacturing the silicon carbide substrate according to claim 1, wherein the step of forming said sublimation preventing layer is performed using a sputtering method.

5. The method for manufacturing the silicon carbide substrate according to claim 1, wherein the step of forming said sublimation preventing layer includes the steps of
applying a fluid containing carbon atoms onto said first region, and
carbonizing said fluid thus applied.

6. The method for manufacturing the silicon carbide substrate according to claim 5, wherein said fluid is an adhesive agent.

7. The method for manufacturing the silicon carbide substrate according to claim 5, wherein said fluid is a photoresist.

8. A silicon carbide substrate comprising:
a base substrate having a main surface and made of silicon carbide;
a sublimation preventing layer made of a material having a solid state at a sublimation temperature of silicon carbide, and covering a portion of said main surface; and
first and second single-crystal layers arranged on said base substrate and made of silicon carbide, said first single-crystal layer having a first backside surface, a first front-side surface opposite to said first backside surface, and a first side surface connecting said first backside surface and said first front-side surface to each other, said second single-crystal layer having a second backside surface, a second front-side surface opposite to said second backside surface, and a second side surface connecting said second backside surface and said second front-side surface to each other, each of said first and second backside surfaces being connected to said base substrate, a gap between said first and second side surfaces being located over said sublimation preventing layer.
